(19) United States
(12) Patent Application Publication
(10) Pub. No.: US 2022/0359629 A1
(43) Pub. Date: Nov. 10, 2022

(54) DISPLAY PANEL, METHOD FOR MANUFACTURING THE SAME, AND DISPLAY APPARATUS

(71) Applicant: WUHAN TIANMA MICROELECTRONICS CO., LTD., Wuhan (CN)

(72) Inventors: Dan Huang, Wuhan (CN); Shaungli Zhu, Wuhan (CN)

(73) Assignee: WUHAN TIANMA MICROELECTRONICS CO., LTD., Wuhan (CN)

(21) Appl. No.: 17/813,990

(22) Filed: Jul. 21, 2022

(30) Foreign Application Priority Data
May 24, 2022 (CN) 202210570268.3

(51) Int. Cl. H01L 27/32; H01L 51/56; H01L 51/52

(52) U.S. Cl. CPC H01L 27/3246; H01L 51/56; H01L 51/5225; H01L 2227/323

(57) ABSTRACT

A display panel, a method for manufacturing the display panel, and a display apparatus are provided. The display panel has pixel regions and a non-pixel region, and the non-pixel region is at least located between two adjacent pixel regions. The display panel includes a substrate, a light-emitting element layer located at a side of the substrate and comprising an organic common layer, and a first opening located in one of the at least one non-pixel region. The first opening includes a first sidewall and a second sidewall. The first sidewall is a side surface of a first layer, and the second sidewall is a side surface of a second layer. The first layer and the second layer are located at a side of the organic common layer facing towards the substrate, and the organic common layer forms a recessed structure at the first opening.

### CROSS-REFERENCE TO RELATED APPLICATION

The present application claims the benefit of Chinese Patent Application No. 202210570268.3, filed on May 24, 2022, the content of which is incorporated herein by reference in its entirety.

### TECHNICAL FIELD

The present disclosure relates to the field of display technologies, and, particularly, relates to a display panel, a method for manufacturing the display panel, and a display apparatus.

### BACKGROUND

Compared with a liquid crystal display (LCD) panel, an organic light-emitting diode (OLED) panel has the advantages of self-luminescence, high luminous efficiency, low power consumption, fast response, wide viewing angle, high brightness, bright colors, and being light and thin, and so on, which is widely used in various electronic device.

In the related art, when an OLED display panel displays images, if only some pixel regions are to be lit, ideally, other pixel regions that should not be lit should be in a completely non-light-emitting state. However, due to the large leakage current between the lit pixel region and its adjacent pixel region, the adjacent pixel region that should not be lit will be slightly brightened under the leakage current, resulting in an undesirable light emission of the sub-pixels, thereby affecting the display effect.

### SUMMARY

A first aspect of the present disclosure provides a display panel. The display panel has pixel regions and at least one non-pixel region, and each of the at least one non-pixel region is at least located between two adjacent pixel regions of the pixel regions. The display panel includes a substrate, a light-emitting element layer located at a side of the substrate and comprising an organic common layer, and a first opening located in one of the at least one non-pixel region. The first opening includes a first sidewall and a second sidewall. The first sidewall is a side surface of a first layer, and the second sidewall is a side surface of a second layer. The first layer and the second layer are located at a side of the organic common layer facing towards the substrate, and the organic common layer forms a recessed structure at the first opening.

A second aspect of the present disclosure provides a method for manufacturing a display panel. The display panel has pixel regions and at least one non-pixel region, and each of the at least one non-pixel region is at least located between two adjacent pixel regions of the pixel regions. The display panel includes a substrate, a light-emitting element layer located at a side of the substrate and comprising an organic common layer, and a first opening located in one of the at least one non-pixel region. The first opening includes a first sidewall and a second sidewall. The first sidewall is a side surface of a first layer, and the second sidewall is a side surface of a second layer. The first layer and the second layer are located at a side of the organic common layer facing towards the substrate, and the organic common layer forms a recessed structure at the first opening. The method includes: forming the first layer and the second layer on the substrate, where the first sidewall of the first layer and the second sidewall of the second layer form the first opening located in the one of the at least one non-pixel region; and forming the light-emitting element layer at a side of the first layer and the second layer that faces away from the substrate, wherein the light-emitting element layer comprises the organic common layer.

A third aspect of the present disclosure provides a display apparatus. The display apparatus includes a display panel. The display panel has pixel regions and at least one non-pixel region, and each of the at least one non-pixel region is at least located between two adjacent pixel regions of the pixel regions. The display panel includes a substrate, a light-emitting element layer located at a side of the substrate and comprising an organic common layer, and a first opening located in one of the at least one non-pixel region. The first opening includes a first sidewall and a second sidewall. The first sidewall is a side surface of a first layer, and the second sidewall is a side surface of a second layer. The first layer and the second layer are located at a side of the organic common layer facing towards the substrate, and the organic common layer forms a recessed structure at the first opening.

### BRIEF DESCRIPTION OF DRAWINGS

In order to better illustrate technical solutions of embodiments of the present disclosure, the accompanying drawings used in embodiments are briefly described below. The drawings described below are merely a part of some embodiments of the present disclosure.

Based on these drawings, those skilled in the art can obtain other drawings.

FIG. 1 is a cross-sectional view of a display panel in the related art;

FIG. 2 is a cross-sectional view of a display panel provided by some embodiments of the present disclosure;

FIG. 3 is a top view of a display panel provided by some embodiments of the present disclosure;

FIG. 4 is another cross-sectional view of a display panel provided by some embodiments of the present disclosure;

FIG. 5 is a schematic diagram of a first opening provided by some embodiments of the present disclosure;

FIG. 6 is a top view of a disconnection region in an organic common layer provided by some embodiments of the present disclosure;

FIG. 7 is another schematic diagram of a first opening provided by some embodiments of the present disclosure;

FIG. 8 is a schematic view showing a size of a first opening provided by some embodiments of the present disclosure;

FIG. 9 is a schematic diagram of a first layer and a second layer provided by some embodiments of the present disclosure;

FIG. 10 is another cross-sectional view of a display panel provided by some embodiments of the present disclosure;

FIG. 11 is another schematic diagram of the first layer and the second layer provided by some embodiments of the present disclosure;

FIG. 12 is a cross-sectional view of a display panel provided by some embodiments of the present disclosure;

FIG. 13 is a top view of a pixel region and a first opening provided by some embodiments of the present disclosure;

FIG. 14 is a cross-sectional view of FIG. 13 along a direction A1-A2 provided by some embodiments of the present disclosure;

FIG. 15 is another top view of the pixel region and the first opening provided by some embodiments of the present disclosure;

FIG. 16 is a cross-sectional view of FIG. 15 along a direction B1-B2 provided by some embodiments of the present disclosure;

FIG. 17 is a schematic diagram of another arrangement of pixel regions provided by some embodiments of the present disclosure;

FIG. 18 is a schematic diagram of a filling layer provided by some embodiments of the present disclosure;

FIG. 19 is a top view of a first opening provided by some embodiments of the present disclosure;

FIG. 20 is another top view of a first opening provided by some embodiments of the present disclosure;

FIG. 21 is another top view of a first opening provided by some embodiments of the present disclosure;

FIG. 22 is a schematic diagram of a step structure provided by some embodiments of the present disclosure;

FIG. 23 is another schematic diagram of a step structure provided by some embodiments of the present disclosure;

FIG. 24 is a schematic diagram of an organic common layer provided by some embodiments of the present disclosure;

FIG. 25 is a flowchart of a manufacturing method provided by some embodiments of the present disclosure;

FIG. 26 is another flowchart of a manufacturing method provided by some embodiments of the present disclosure;

FIG. 27 is a process flowchart corresponding to FIG. 26 provided by some embodiments of the present disclosure;

FIG. 28 is another process flowchart corresponding to FIG. 26 provided by some embodiments of the present disclosure;

FIG. 29 is another process flowchart provided by some embodiments of the present disclosure; and

FIG. 30 is a schematic diagram of a display apparatus provided by some embodiments of the present disclosure.

### DETAILED DESCRIPTION

In order to better understand the technical solutions of the present disclosure, some embodiments of the present disclosure are described in detail below Referring to the accompanying drawings.

It should be clear that the described embodiments are only some embodiments of the present disclosure, but not all of the embodiments. Based on the embodiments in the present disclosure, all other embodiments obtained by those of ordinary skill in the art without creative efforts fall within the protection scope of the present disclosure.

The terms used in some embodiments of the present disclosure are only for the purpose of describing specific embodiments, and are not intended to limit the present disclosure. As used in some embodiments of the present disclosure and the appended claims, the singular forms “a/an” “the” and “said” are intended to include the plural forms as well, unless the context clearly dictates otherwise.

It should be understood that the term “and/or” used in this document is only an association relationship to describe the associated objects, indicating that there can be three relationships, for example, A and/or B, which can indicate that A alone, A and B, and B alone. The character “/” in this document generally indicates that the related objects are an “or” relationship.

Before describing the technical solutions of the present disclosure, the present disclosure first describes the reasons of undesirable light-emitting of the sub-pixels in the related art.

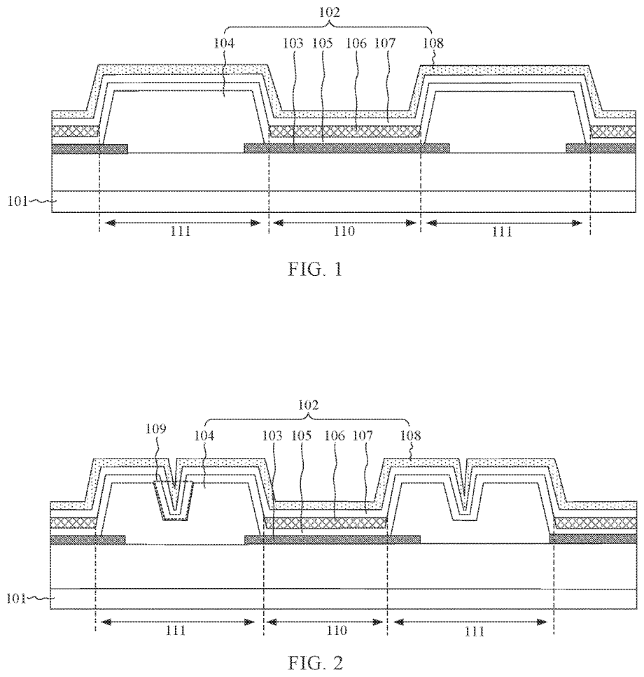

As shown in FIG. 1, FIG. 1 is a cross-sectional view of a display panel in the related art. The display panel includes a substrate 101 and a light-emitting element layer 102 located at a side of the substrate 101. The light-emitting element layer 102 includes an anode 103, a pixel definition layer 104, a hole transmission layer 105, a light-emitting layer 106, and a cathode 108. The pixel definition layer 104 is located at a side of the anode 103 facing away from the substrate 101. The pixel definition layer 104 includes an opening for defining a pixel region 110. The hole transmission layer 105 is located at a side of the pixel definition layer 104 facing away from the substrate 101. The light-emitting layer 106 is located in an opening. The electron transmission layer 107 is located at a side of the light-emitting layer 106 facing away from the substrate 101. The cathode 108 is located at a side of the electron transmission layer 107 facing away from the substrate 101. The hole transmission layer 105 and the electron transmission layer 107 each are a whole layer, that is, the hole transmission layer 105 and the electron transmission layer 107 cover the pixel region 110 and the non-pixel region 111.

When the pixel region 110 is controlled to be lit, the anode 103 and the cathode 108 in the pixel region 110 receive corresponding driving voltages, respectively. At this time, holes migrate to the light-emitting layer 106 through the hole transmission layer 105. Electrons migrate to the light-emitting layer 106 through the electron transmission layer 107. Holes and electrons meet in the light-emitting layer 106 to form excitons which excite the light-emitting molecules in the light-emitting layer 106 to emit visible light.

However, since the hole transmission layer 105 and the electron transmission layer 107 each are a whole layer, that is, the organic common layers between adjacent pixel regions 110 are also connected to each other, when only some pixel regions 110 need to be controlled to be lit, the holes injected into the hole transmission layer 105 and the electrons injected into the electron transmission layer 107 in the lit pixel regions 110 will migrate to their adjacent light-emitting layer 106 of the pixel region 110 that should not be lit, the pixel region 110 that should not be lit is then lit, resulting in the phenomenon of undesirable light-emitting of sub-pixels.

In order to improve the problem of undesirable light-emitting, as shown in FIG. 2, which is a cross-sectional view of a display panel provided by some embodiments of the present disclosure, a groove 109 can be provided in the pixel definition layer 104, so that the hole transmission layer 105 and the electron transmission layer 107 are recessed at the groove 109 to increase the extension length of this part of the organic common layer that is located between adjacent pixel regions 110, thereby increasing the impedance of this part of the organic common layer, and suppressing the mobility of electrons/holes between adjacent pixel regions 110.

However, only increasing the impedance of the organic common layer can improve the current leakage problem to a certain extent, but the effect is not improved significantly.

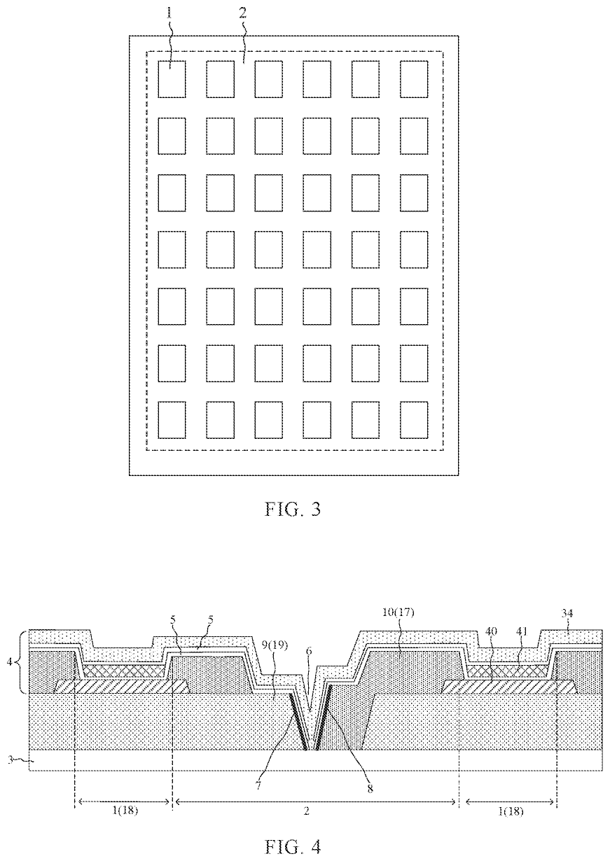

In this regard, the present disclosure provides a display panel. FIG. 3 is a top view of a display panel provided by some embodiments of the present disclosure. As shown in FIG. 3, the display panel includes multiple pixel regions 1 and a non-pixel region 2 at least located between two adjacent pixel regions 1. The pixel region 1 can be understood as an opening region of the sub-pixel, that is, a region where the light-emitting layer is located, and the non-pixel region 2 can be understood as a non-opening region of the sub-pixel.

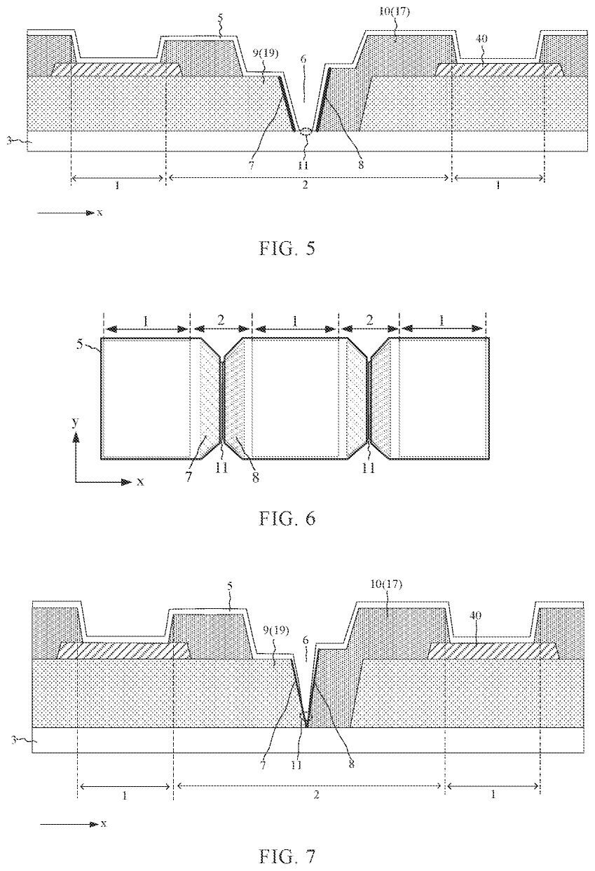

FIG. 4 is another cross-sectional view of a display panel provided by some embodiments of the present disclosure, and FIG. 5 is a schematic diagram of a first opening provided by some embodiments of the present disclosure. As shown in FIG. 4 and FIG. 5, the display panel includes a substrate 3, a light-emitting element layer 4 located at a side of the substrate 3, and a first opening 6. The light-emitting element layer 4 includes an organic common layer 5. The first opening 6 is located in a non-pixel region 2. The first opening 6 includes a first sidewall 7 and a second sidewall 8. The first sidewall 7 is a side surface of a first layer 9. The second sidewall 8 is a side surface of a second layer 10. The first layer 9 and the second layer 10 are both located at a side of the organic common layer 5 facing towards the substrate 3.

In some embodiments of the present disclosure, the first opening 6 is defined by the sidewalls of two different layers, i.e., the first layer 9 and the second layer 10. The first layer 9 and the second layer 10 are two layers formed by different film forming processes. For example, a first film forming process can be used to form the first layer 9 first, and then secondary second film forming process can be used to form the second layer 10. In some embodiments, the second layer 10 can be formed by the first film forming process first, and then the first layer 9 can be formed by the second film forming process.

If the first opening 6 is described in another perspective, it can be as follows: the display panel can include an auxiliary layer located at a side of the substrate 3 facing towards the organic common layer 5. The auxiliary layer includes a first layer 9 and a second layer 10. The auxiliary layer can include a first opening 6 located in the non-pixel region. A first sidewall 7 of the first opening 6 belongs to the first layer 9, and a second sidewall 8 of the first opening 6 belongs to the second layer 10.

The openings in the panel in the related art, such as a groove 109 shown in FIG. 2, are usually formed by etching a single layer, and the sidewalls of such openings are all belong to a same layer. Limited by the current process ability, the shape of this type of opening is largely limited. For example, most of this type of opening is an inverted trapezoidal opening with a large bottom width and a large top width, and its corresponding volume is also large.

The first opening 6 in the present disclosure is different from the above opening. The sidewalls of the first opening 6 in some embodiments of the present disclosure respectively belong to two different layers. In this case, by adjusting the inclination angle between the sidewalls of the two layers and the bottom surface, the relative positional relationship of the two layers and the etching area of the two layers, etc., the inclination degrees of the first sidewall 7 and the second sidewall 8 of the first opening 6, a distance between the first sidewall 7 and the second sidewall 8, etc. can be flexibly adjusted to realize flexible regulation of parameters such as the shape and volume of the first opening 6. For example, in some embodiments of the present disclosure, two layers can be used to form a slit-shaped first opening 6 with a small volume to form a V-shaped structure. In this way, when the organic common layer 5 forms a recessed structure at the first opening 6, there will be a stress concentration point at this part of the layer at the bottom of the first opening 6, so that a natural fracture occurs at this part of the layer under the intrinsic stress of the layer, high temperature, and external force, and a disconnection region 11 is formed to separate the organic common layer 5 located between two adjacent pixel regions 1, thereby effectively avoiding the mutual flow of holes and electrons between the adjacent pixel regions 1.

In this way, when only some pixel regions 1 need to be controlled to be lit, the lit pixel region 1 will no longer transmit holes and electrons to their adjacent pixel regions 1, thereby avoiding undesirable light-emitting in the adjacent pixel regions 1. In other words, in some embodiments of the present disclosure, based on the current process capability, the organic common layer 5 between adjacent pixel regions 1 can be separated by openings, and the flow of holes and electrons between adjacent pixel regions 1 can be effectively blocked.

In some embodiments, referring to FIG. 4 again, the light-emitting element layer 4 includes a cathode 34 located at a side of the organic common layer 5 facing away from the substrate 3. Since the first layer 9 and the second layer 10 can be used to form the first opening 6 with a relatively small volume in some embodiments of the present disclosure, the organic common layer 5 can fill the first opening 6 to a greater extent as multiple organic common layers 5 forms a recessed structure at the first opening 6. When the cathode 34 is subsequently formed, it can be ensured that the cathode 34 is continuous at the first opening 6, to avoid disconnection of the cathode 34 and improve the continuity of the cathode 34.

In some embodiments, referring to FIG. 5 again, the organic common layer 5 includes a disconnection region 11. In a direction perpendicular to a plane of the substrate 3, the disconnection region 11 overlaps with the first opening 6, to effectively separate the organic common layers 5 in adjacent pixel regions 1, thereby avoiding mutual flow of holes and electrons between different pixel regions 1.

In some embodiments, referring to FIG. 5 again, the first sidewall 7 and the second sidewall 8 are two opposite sidewalls of the first opening 6, so that the first sidewall 7 and the second sidewall 8 can be used to better define the shape of the first opening 6, which is conducive to forming the slit-shaped first opening 6. Therefore, the organic common layer 5 is more likely to have a stress concentration point at the bottom of the first opening 6.

In some embodiments, the first opening 6 is at least located between two adjacent pixel regions 1. The first sidewall 7 and the second sidewall 8 are two sidewalls of the first opening 6 opposite to each other in the first direction x, and overlap at least in the first direction x. The first direction x is a direction along which the pixel regions 1 at both sides of the non-pixel region 2 where the first opening 6 is located, are arranged. FIG. 6 is a top view of the disconnection region 11 in the organic common layer 5 provided by some embodiments of the present disclosure. In this case, as shown in FIG. 6, when the organic common layer 5 is disconnected at the bottom of the first opening 6, the disconnection region 11 formed by the organic common layer 5 at the bottom of the first opening 6 extends along a second direction y intersecting with the first direction x, to be conducive to blocking the mutual flow of holes and electrons between two adjacent pixel regions 1 in the first direction x.

In some embodiments, referring to FIG. 5 again, along a direction from the organic common layer 5 to the substrate 3, the first sidewall 7 is inclined towards the second sidewall 8, and the second sidewall 8 is inclined towards the first sidewall 7. In other words, along the direction from the organic common layer 5 to the substrate 3, a distance between the first sidewall 7 and the second sidewall 8 in the first direction x decreases. That is, a width of the first opening 6 decreases, thereby reducing a bottom width of the first opening 6. When the organic common layer 5 forms a recessed structure at the first opening 6, the organic common layer 5 is subjected to a greater stress at the bottom of the first opening 6, and the possibility of fracture is relatively high.

FIG. 7 is another schematic diagram of the first opening 6 provided by some embodiments of the present disclosure. In some embodiments, as shown in FIG. 7, the first sidewall 7 and the second sidewall 8 intersect with each other, that is, a bottom of the first sidewall 7 is in contact with a bottom of the second sidewall 8, the first opening 6 is a V-shaped slit structure, a bottom of the first opening 6 is a sharp corner, and the organic common layer 5 is liable to be fractured at the bottom of the first opening 6.

The organic common layer 5 is very thin, generally at a nanometer level. In a manufacturing process of the display panel, affected by the process capability, the organic common layer 5 deposited at a sidewall of the layer will be thinned, for example, along a direction towards the bottom of the first opening 6, the thickness of the organic common layer 5 decreases. In this way, it not only makes the organic common layer 5 at the bottom of the first opening 6 easier to fracture under stress, but also makes the organic common layers 5 extending on the first sidewall 7 and the second sidewall 8 not contact with each other after the organic common layer 5 fractures, so that the organic common layer 5 is effectively disconnected.

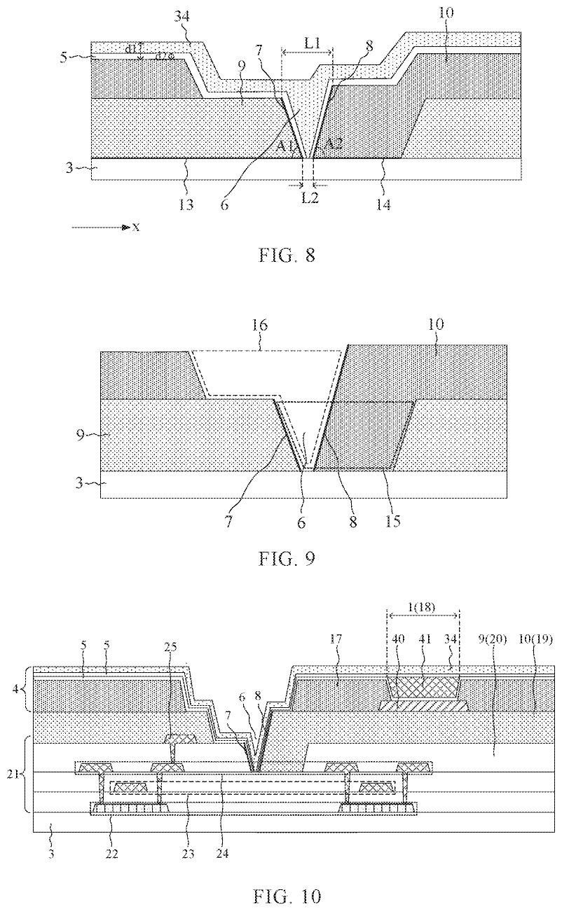

FIG. 8 is a schematic view showing a size of a first opening 6 provided by some embodiments of the present disclosure. In an embodiment, as shown in FIG. 8, the first layer 9 includes a first bottom surface 13 close to the substrate 3, an angle A1 between the first sidewall 7 and the first bottom surface 13 satisfies 60°<A1<90°, the second layer 10 includes a second bottom surface 14 at a side close to the substrate 3, and an angle A2 between the second sidewall 8 and the first bottom surface 14 satisfies 60°<A2<90°.

The light-emitting element layer 4 also includes a cathode 34 located at a side of the organic common layer 5 facing away from the substrate 3. In the first direction x, a maximum distance L1 between the first sidewall 7 and the second sidewall 8 satisfies L1<2×d1, where d1 is a sum of the film thicknesses of the cathode 34 and the organic common layer 5, and the first direction x is a direction along which the pixel regions 1 at both sides of the non-pixel region 2 where the first opening 6 is located are arranged.

The thicknesses of the cathode 34 and the organic common layer 5 can be understood as the thicknesses of the cathode 34 and the organic common layer 5 in the pixel region 1. If there are multiple organic common layers 5, d1 denotes a sum of a thickness of the cathode 34 and a thickness of multiple organic common layers 5.

In some embodiments of the present disclosure, by setting L1 within a range smaller than or equal to 2×d1, and on the premise that A1 and A2 are within a range from 60° to 90°, the top widths L1 and L2 of the first opening 6 will not be very large. In this case, the shape of the first opening 6 is defined as a very narrow slit that tends to a V-shaped structure, so that the organic common layer 5 at the bottom of the first opening 6 is more likely to have a stress concentration point and thus be more easily disconnected.

In some embodiments, by designing the top width L1 of the first opening to be smaller than twice the sum of the thicknesses of the cathode 34 and the organic common layer 5, the top of the first opening 6 can be prevented from being excessively wide. When one or more organic common layers 5 forms a recessed structure at the first opening 6, the first opening 6 can be substantially filled entirely with the organic common layer 5 extending on the first sidewall 7 and the second sidewall 8. When the cathode 34 is subsequently formed, the cathode 34 will not be recessed deeply at the first opening 6, so that the fluctuation of the cathode 34 at the first opening 6 can be reduced, and the continuity of the cathode 34 can be ensured to a greater extent, avoiding the disconnection of the cathode 34.

In some embodiments, referring to FIG. 8 again, in the first direction x, the minimum distance L2 between the first sidewall 7 and the second sidewall 8 satisfies L2>2×d2, where d2 denotes a thickness of the organic common layer 5. If there are multiple organic common layers 5, d2 denotes a sum of the thicknesses of the multiple organic common layers 5. In this case, when the organic common layer 5 is disconnected at the bottom of the first opening 6, the organic common layer 5 extending on the first sidewall 7 and the organic common layer 5 extending on the second sidewall 8 can be prevented from contacting with each other at the bottom, which is conducive to blocking the holes and the electrons.

FIG. 9 is a schematic diagram of the first layer 9 and the second layer 10 provided in some embodiments of the present disclosure. In an embodiment, as shown in FIG. 9, the second layer 10 is located at a side of the first layer 9 facing away from the substrate 3. The first layer 9 includes a first groove 15, and the second layer 10 includes a second groove 16. In the direction perpendicular to the plane of the substrate 3, the second groove 16 partially overlaps with the first groove 15, and a part of the second layer 10 is recessed at the first groove 15. A sidewall of the second layer 10 recessed at the first groove 15 is the second sidewall 8, and a sidewall of the first layer 9 opposite to the second sidewall 8 is the first sidewall 7.

With the above configuration, the first layer 9 and the second layer 10 are two layers arranged in different layers. By staggering the grooves in two layers to form the first opening 6, in addition to better forming the V-slit-shaped first opening 6 to fracture the organic common layer 5, a step surface with fluctuation is formed between a part of the first layer 9 exposed in the second groove 16 and the second layer 10 located above this part of the first layer 9. Compared with providing grooves in a single layer, the present disclosure can increase a length of the part of the organic common layer 5 extending in the non-pixel region 2 to a greater extent, so that the impedance of this part of the organic common layer 5 is increased to a greater extent, thereby suppressing the flow of holes and electrons in the pixel region 1 to the surrounding more effectively.

In an embodiment, referring to FIG. 4 again, the light-emitting element layer 4 includes a pixel definition layer 17 located at a side of the organic common layer 5 facing towards the substrate 3. The pixel definition layer 17 includes a second opening 18 for defining the pixel region 1. The display panel can include a planarization layer 19 located at a side of the pixel definition layer 17 facing towards the substrate 3. The first layer 9 is the planarization layer 19, and the second layer 10 is the pixel definition layer 17.

In the panel structure, the planarization layer 19 is configured to planarize the layer, so the planarization layer 19 usually has a large thickness. By reusing the planarization layer 19 as the first layer 9, the planarization layer 19 can be used to form the first opening 6 with a large depth, the organic common layer 5 is easily fractured at the junction of the top surface of the planarization layer 19 and the first sidewall 7 in addition to the fracture at the bottom of the first opening 6. The organic common layer 5 is disconnected at multiple positions, the flow of holes and electrons between adjacent pixel regions 1 can be blocked to a greater extent. Since the organic common layer 5 is in direct contact with the pixel definition layer 17 in the non-pixel region 2, when the planarization layer 19 is reused as the first layer 9, and the pixel definition layer 17 is reused as the second layer 10, the organic common layer 5 can be directly recessed at the first opening 6 formed by the planarization layer 19 and the pixel definition layer 17, there is no other layers under the organic common layer 5, so the organic common layer 5 is more likely to have sharp corners at the bottom of the first opening 6, and the stress is more concentrated, thereby being more prone to fracture.

By reusing the planarization layer 19 as the first layer 9, and reusing the pixel definition layer 17 as the second layer 10, the first groove 15 and the second groove 16 can be respectively etched in the planarization layer 19 and the pixel definition layer 17 by only respectively changing the mask patterns corresponding to the pixel definition layer 17 and the planarization layer 19, which not only does not need to add a new process, but also lowers the process cost. In this way, it will not lead to an increase in the overall thickness of the panel, which is more conducive to achieve a thin and light display panel.

FIG. 10 is another cross-sectional view of a display panel provided by some embodiments of the present disclosure; and FIG. 11 is another schematic diagram of the first layer 9 and the second layer 10 provided by some embodiments of the present disclosure. In another embodiment, the light-emitting element layer 4 includes a pixel definition layer 17 located at a side of the organic common layer 5 facing towards the substrate 3. The pixel definition layer 17 includes a second opening 18 configured to define the pixel region 1. The display panel can include a planarization layer 19 and a first insulation layer 20. The planarization layer 19 is located at a side of the pixel definition layer 17 facing towards the substrate 3, and the first insulation layer 20 is located at a side of the planarization layer 19 facing towards the substrate 3. The first layer 9 is the first insulation layer 20, and the second layer 10 is the planarization layer 19.

In some embodiments, referring to FIG. 10, the display panel includes a circuit device layer 21, and the circuit device layer 21 includes a semiconductor layer 22, a first metal layer 23, a second metal layer 24, and a third metal layer 25 that are sequentially arranged in a direction facing away from the substrate 3. The semiconductor layer 22 is used to form an active layer of the transistor. The first metal layer 23 is used to form a gate of the transistor. The second metal layer 24 is used to form a first electrode and a second electrode of the transistor. The third metal layer 25 is used to form power supply signal lines electrically connected to the transistors. The planarization layer 19 is located at a side of the third metal layer 25 facing away from the substrate 3. The first insulation layer 20 can be an insulation layer between the second metal layer 24 and the third metal layer 25.

Since the planarization layer 19 has a relatively large thickness, when the planarization layer 19 is reused as the second layer 10, the extension length of the second sidewall 8 is relatively large, except that the organic common layer 5 is fractured at the bottom of the first opening 6, the organic common layer 5 is also easy to fracture at the junction between the top surface of the planarization layer 19 and the second sidewall 8, thereby blocking the flow of holes and electrons between adjacent pixel regions 1 to a greater extent.

By reusing the first insulation layer 20 as the first layer 9, and reusing the planarization layer 19 as the second layer 10, the first groove 15 and the second groove 16 can be respectively etched on the first insulation layer 20 and the planarization layer 19 by only change the mask patterns corresponding to the first insulation layer 20 and the planarization layer 19, respectively, which not only does not need to add a new process, but also lowers the process cost. In this way, it will not lead to an increase in the overall thickness of the panel, which is more conducive to achieve a thin and light display panel.

In some embodiments, referring to FIG. 11 again, the pixel definition layer 17 includes a third opening 26. In the direction perpendicular to the plane of the substrate 3, the third opening 26 at least exposes the first opening 6. In this case, the pixel definition layer 17 is not recessed at the first opening 6 formed by the planarization layer 19 and the first insulation layer 20. During forming the organic common layer 5, it can be avoided that the first opening 6 is filled with the pixel definition layer 17, so that the organic common layer 5 is more likely to be fracture at the bottom of the first opening 6. The overall groove depth formed by the above three layers is larger, so the extension length of the organic common layer 5 between the non-pixel regions 2 is larger and the impedance is higher.

In some embodiments, referring to FIG. 11 again, in the direction perpendicular to the plane of the substrate 3, the second groove 16 is located in the third opening 26. In this case, a step can be formed between the pixel definition layer 17 and the planarization layer 19, thereby increasing the impedance of the organic common layer 5 in the non-pixel region 2, and suppressing the flow of holes and electrons in the pixel region 1 to the surrounding region to a greater extent.

In some embodiments, referring to FIG. 9 and FIG. 11 again, the first groove 15 penetrates the first layer 9, and the second groove 16 penetrates the second layer 10, so that the depth of the first opening 6 is increased, thereby causing the organic common layer 5 to fracture more likely at the bottom of the first opening 6.

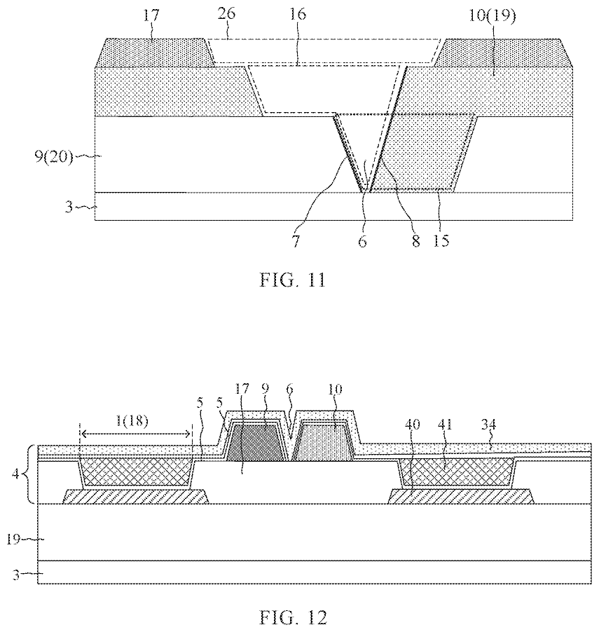

FIG. 12 is a cross-sectional view of a display panel provided by some embodiments of the present disclosure. In an embodiment, as shown in FIG. 12, the light-emitting element layer 4 includes a pixel definition layer 17 located at a side of the organic common layer 5 facing towards the substrate 3, and the pixel definition layer 17 includes a second opening 18 for defining the pixel region 1.

The first layer 9 and the second layer 10 are located between the pixel definition layer 17 and the organic common layer 5, and are arranged in a same layer. Although the first layer 9 and the second layer 10 are arranged in the same layer, the first layer 9 and the second layer 10 are formed through two patterning processes, respectively.

With this configuration, the first layer 9 and the second layer 10 are located on an upper side of the pixel definition layer 17 and are arranged in a same layer. In this case, the shape of the first opening 6 can be flexibly regulated directly by adjusting the thickness of the first layer 9 and the second layer 10, and adjusting a distance between the first layer 9 and the second layer 10, thereby achieving a simpler design of the first opening 6.

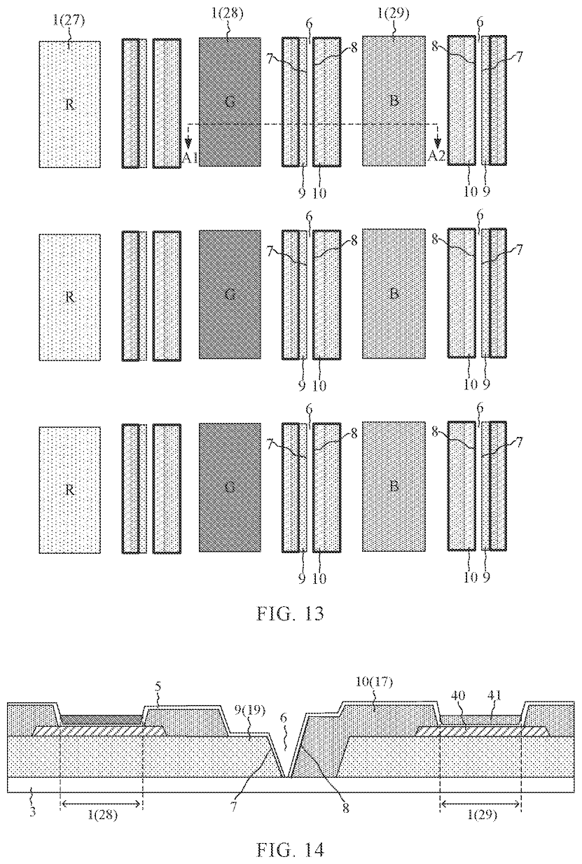

FIG. 13 is a top view of a pixel region 1 and a first opening 6 provided by some embodiments of the present disclosure, and FIG. 14 is a cross-sectional view of FIG. 13 along a direction A1-A2 provided by some embodiments of the present disclosure. In an embodiment, as shown in FIG. 13 and FIG. 14, the pixel region 1 includes a red pixel region 27 for emitting red light, a green pixel region 28 for emitting green light, and a blue pixel region 29 for emitting blue light. The second layer 10 is located at a side of the first layer 9 facing away from the substrate 3, and the blue pixel region 29 is located at a side of the second sidewall 8 of the first opening 6.

When the second layer 10 is located at a side of the first layer 9 facing away from the substrate 3, the layer height at the second sidewall 8 is larger, and the organic common layer 5 is easily fractured at the top edge of the second sidewall 8 in addition to be fractured at the bottom of the first opening 6, therefore the reliability of disconnection of the organic common layer 5 at the second sidewall 8 is higher. The extension length of the second sidewall 8 is large, and the impedance of the organic common layer 5 extending on the second sidewall 8 is also large. Therefore, the holes and electrons of the pixel region 1 at a side of the second sidewall 8 are less likely to flow to the second sidewall 8, that is, the effect of suppressing the current leakage is good at a side of the second sidewall 8.

Since the blue pixel region 29 has a higher light-on voltage than the red pixel region 27 and the green pixel region 28, when the blue pixel region 29 is lit, the undesirable light-emitting of the red pixel region 27 and the green pixel region 28 more likely occurs due to current leakage. In some embodiments of the present disclosure, by arranging the blue pixel region 29 at a side of the second sidewall 8 with a better suppressing effect on current leakage, so that the undesirable light-emitting of the red pixel region 27 and the green pixel region 28 can be better blocked when the blue pixel region 29 is lit.

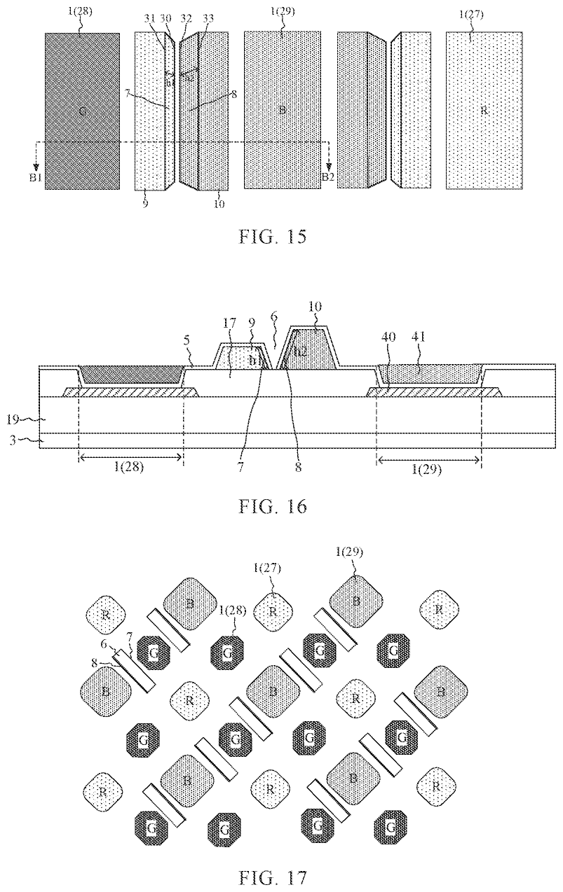

FIG. 15 is another top view of the pixel region 1 and the first opening 6 provided by some embodiments of the present disclosure; and FIG. 16 is a cross-sectional view of FIG. 15 along a direction B1-B2 provided by some embodiments of the present disclosure. In an embodiment, as shown in FIG. 15 and FIG. 16, the first sidewall 7 includes a first bottom edge 30 at a side close to the substrate 3, and a first top edge 31 at a side away from the substrate 3. The second sidewall 8 includes a second bottom edge 32 at a side close to the substrate 3, and a second top edge 33 at a side away from the substrate 3. A distance h2 between the second top edge 33 and the second bottom edge 32 in the second sidewall 8 is greater than a distance h1 between the top edge 31 and the first bottom edge 30 in the first sidewall 7.

The pixel region 1 includes a red pixel region 27 for emitting red light, a green pixel region 28 for emitting green light, and a blue pixel region 29 for emitting blue light. The blue pixel region 29 is located a side of the sidewall 8 of the first opening 6.

Since the layer height of the second sidewall 8 is higher, on the one hand, the organic common layer 5 is easily fractured at the intersection of the second sidewall 8 and the top surface of the second layer 10 in addition to be fractured at the bottom of the first opening 6. On the other hand, the impedance of the organic common layer 5 extending on the second sidewall 8 is also higher, so the suppressing effect on the current leakage at a side of the second sidewall 8 is better. By arranging the blue pixel region 29 at a side of the second sidewall 8 with a better suppressing effect on current leakage, the undesirable light-emitting of the red pixel region 27 and the green pixel region 28 can be better blocked when the blue pixel region 29 is lit.

In some embodiments of the present disclosure, the pixel region 1 can adopt the arrangement manners shown in FIG. 13 and FIG. 15. FIG. 17 is a schematic diagram of another arrangement of the pixel region 1 provided by some embodiments of the present disclosure. In some embodiments, as shown in FIG. 17, the pixel region 1 can also adopt a pinwheel arrangement shown in FIG. 17 or other arrangements, which is not limited in the present disclosure.

Since the volume of the first opening 6 formed in some embodiments of the present disclosure is relatively small, as the layer number of the organic common layer 5 deposited in the first opening 6 increases, the first opening 6 is easier to be filled. In an embodiment, referring to FIG. 4 again, the light-emitting element layer 4 includes a cathode 34 located at a side of the organic common layer 5 facing away from the substrate 3. The cathode 34 communicates in the pixel region 1 and the non-pixel region 2. That is, in the direction perpendicular to the plane of the substrate 3, the cathode 34 overlaps with the disconnection region 11 of the organic common layer 5, thereby ensuring that the cathode 34 is continuous in both the pixel region 1 and the non-pixel region 2.

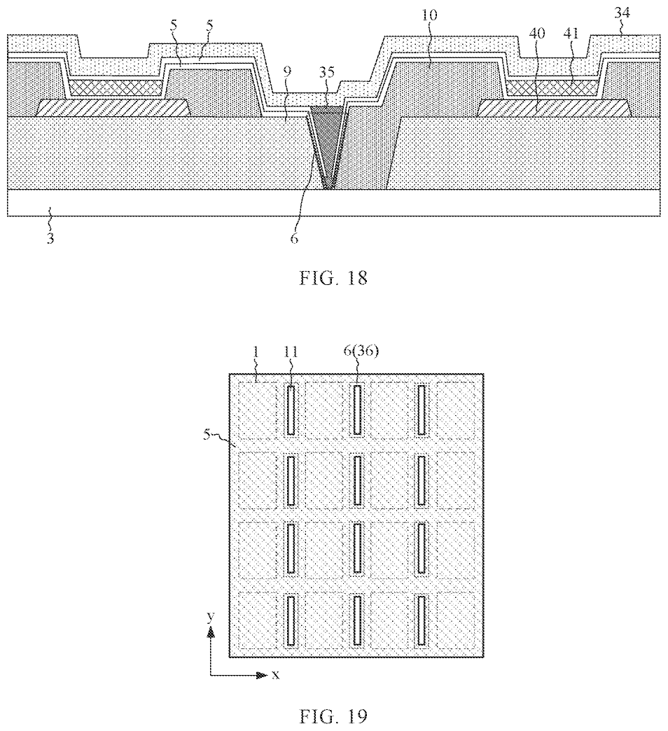

FIG. 18 is a schematic diagram of a filling layer 35 provided by some embodiments of the present disclosure. In some embodiments, as shown in FIG. 18, the light-emitting element layer 4 includes a cathode 34 located at a side of the organic common layer 5 facing away from the substrate 3. The display panel can include a filling layer 35. The filling layer 35 is located in the first opening 6 and located between the organic common layer 5 and the cathode 34. If the first opening 6 is deep, the filling layer 35 can be used to fill the first opening 6 to prevent the cathode 34 from being recessed at the first opening 6, thereby ensuring the continuity of the cathode 34 to a greater extent.

FIG. 19 is a top view of a first opening 6 provided by some embodiments of the present disclosure. In an embodiment, as shown in FIG. 19, the first opening 6 includes a strip-shaped opening 36. The extension direction of the strip-shaped opening 36 intersects with the direction along which the pixel regions 1 at both sides of the non-pixel region 2 where the strip opening 36 is located are arranged. In this case, the extension direction of the disconnection regions 11 in the organic common layer 5 also intersects with the direction along which the pixel regions 1 at both sides of the non-pixel region 2 where the strip opening 36 is located are arranged, therefore, it is more beneficial to block the mutual flow of holes and electrons between two adjacent pixel regions 1.

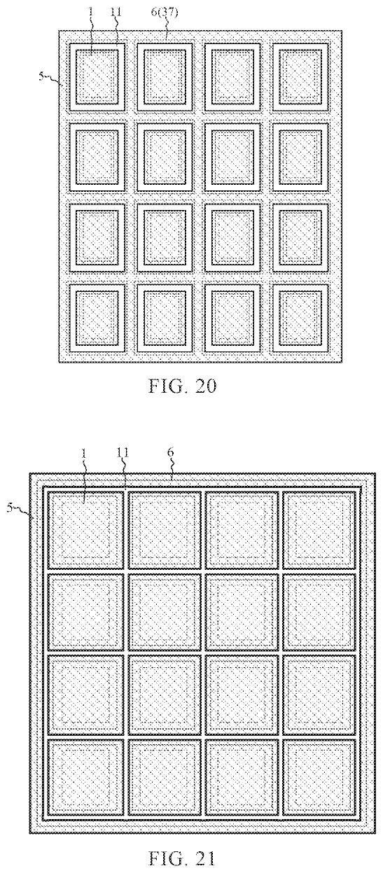

FIG. 20 is another top view of a first opening 6 provided by some embodiments of the present disclosure. In an embodiment, as shown in FIG. 20, the first opening 6 includes an annular opening 37 that surrounds the pixel region 1. In this case, the disconnection region 11 in the organic common layer 5 is also arranged surrounding the pixel region 1, which can suppress the flow of holes and electrons in the pixel region 1 to the surrounding in all directions.

FIG. 21 is another top view of a first opening 6 provided by some embodiments of the present disclosure. In an embodiment, as shown in FIG. 21, the first opening 6 is grid-shaped having holes. In a direction perpendicular to the plane of the substrate 3, the pixel region 1 is exposed in the hole of the first opening 6. Such arrangement can suppress the flow of holes and electrons in the pixel region 1 to the periphery of the pixel region 1, and is more suitable for a display panel with a high pixel density in which the pixel regions 1 are more compactly arranged.

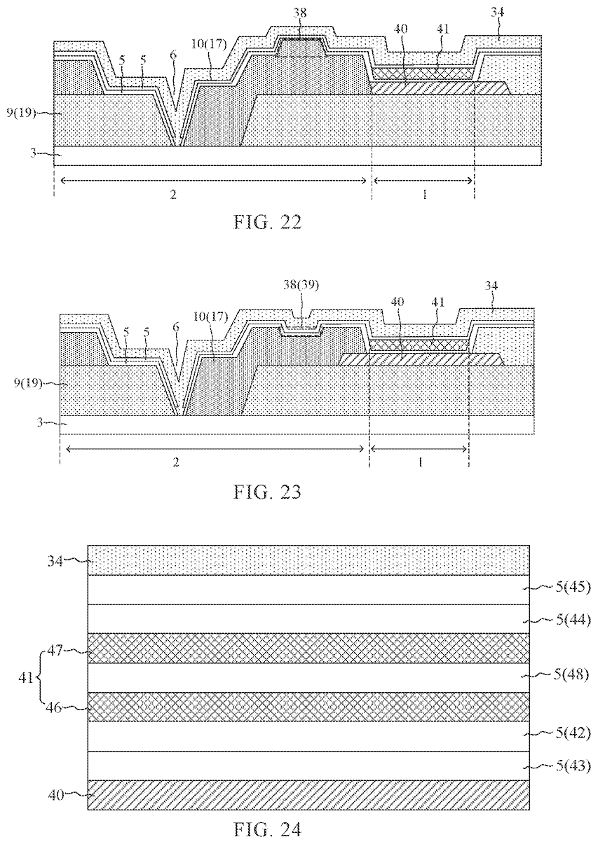

FIG. 22 is a schematic diagram of a step structure 38 provided by some embodiments of the present disclosure, and FIG. 23 is another schematic diagram of a step structure 38 provided by some embodiments of the present disclosure. In an embodiment, as shown in FIG. 22 and FIG. 23, the display panel also includes a step structure 38. The step structure 38 is located in the non-pixel region 2 and located at a side of the organic common layer 5 facing towards the substrate 3, so that the step structure 38 increases the impedance of the organic common layer 5 extending in the non-pixel region 2, thereby suppressing the flow of holes and electrons in the pixel region 1 to the periphery of the pixel region 1.

The step structure 38 can be formed by the first layer 9, the second layer 10, or another layer that is located at a side of the organic common layer 5 facing towards the substrate 3. Taking the first layer 9 as the planarization layer 19 and the second layer 10 as the pixel definition layer 17 as an example, the step structure 38 can be formed by the pixel definition layer 17.

The step structure 38 can be a protrusion. In some embodiments, the display panel can also include a spacer located in the non-pixel region 2. In the manufacturing process of the display panel, the spacer is configured to support a mask plate for forming the light-emitting layer. When the step structure is a protrusion, the step structure can be reused as the spacer, so that there is no need to add an additional process for forming the step structure.

In some embodiments, the step structure 38 can also be a groove. Referring again to FIG. 23, the light-emitting element layer 4 includes a cathode 34 located at a side of the organic common layer 5 facing away from the substrate 3. The step structure 38 includes a third groove 39. In the direction perpendicular to the plane of the substrate 3, a depth of the third groove 39 is greater than the thickness of the organic common layer 5, and is smaller than or equal to a sum of the thickness of the common layer 5 and the thickness of the cathode 34.

With such configuration, the organic common layer 5 is recessed at the third groove 39. While the extension length of the organic common layer 5 is increased by using the third groove 39, the depth of the third groove 39 is small, and the recessed organic common layer 5 can basically fill the third groove 39, so that the subsequent cathode 34 will not be greatly recessed at the third groove 39, thereby better ensuring the continuity of the cathode 34.

Different from the first opening 6, the third groove 39 is a groove formed by etching a single layer, and the sidewalls of the third groove 39 are all formed by a same layer. Therefore, the third groove 39 has a different shape from the first opening 6. The third groove 39 can be an inverted trapezoidal groove with a larger volume, and an angle between the sidewall and the bottom surface of the layer for forming the third groove 39 can range from 60° to 70°.

FIG. 24 is a schematic diagram of an organic common layer 5 provided by some embodiments of the present disclosure. In an embodiment, as shown in FIG. 24, the light-emitting element layer 4 includes an anode 40 located at a side of the substrate 3, the light-emitting layer 41 located at a side of the anode 40 facing away from the substrate 3, and a cathode 34 located at a side of the light-emitting layer 41 facing away from the substrate 3.

Referring again to FIG. 24, the organic common layer 5 includes a hole transmission layer 42 and a hole injection layer 43 that are located between the anode 40 and the light-emitting layer 41; and/or, the organic common layer 5 includes an electron transmission layer 44 and an electron injection layer 45 located between the light-emitting layer 41 and the cathode 34; and/or, the light-emitting layer 41 includes a first light-emitting layer 46 and a second light-emitting layer 47, and in a direction perpendicular to the plane of the substrate 3, the first light-emitting layer 46 and the second light-emitting layer 47 overlap with each other. The organic common layer 5 includes a charge generating layer 48 located between the first light-emitting layer 46 and the second light-emitting layer 47 to effectively block the mutual flow of holes and electrons between different pixel regions 1.

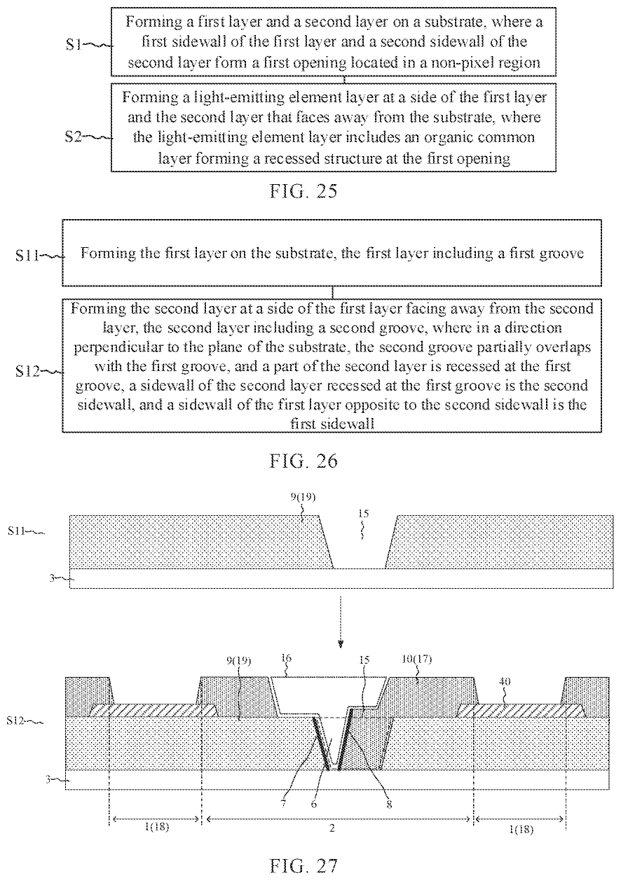

Based on the same or related concepts, the present disclosure also provides, in another aspect, a method for manufacturing a display panel mentioned above. FIG. 25 is a flowchart of a manufacturing method provided by some embodiments of the present disclosure.

Referring to FIG. 3 to FIG. 5, as shown in FIG. 25, the method for manufacturing the display panel includes step S1 and step S2.

At step S1, a first layer 9 and a second layer 10 are formed on a substrate 3, where the first sidewall 7 of the first layer 9 and the second sidewall 8 of the second layer 10 are formed in the first opening 6 of the non-pixel region 2.

At step S2, a light-emitting element layer 4 is formed at a side of the first layer 9 and the second layer 10 facing away from the substrate 3. The light-emitting element layer 4 includes an organic common layer 5 forming a recessed structure at the first opening 6.

Different from the openings in the panel in the related art, the sidewalls of the first opening 6 in some embodiments of the present disclosure respectively belong to two different layers. The inclination degree of the first sidewall 7 and the second sidewall 8 of the first opening 6, and the distance between the first sidewall 7 and the second sidewall 8 can be flexibly adjusted by adjusting the inclination angle between the sidewall and the bottom surface of two layers, relative positional relationship of the two layers, and the etching area of the two layers, etc., so as to realize the flexible regulation of the parameters such as the shape and volume of the first opening 6. For example, in some embodiments of the present disclosure, two layers can be used to form the first opening 6 with a small volume and a V-shaped slit-like structure. In this way, when the organic common layer 5 is recessed at the first opening 6, there will be a stress concentration point in this part of the layer at the bottom of the first opening 6, so that a natural fracture of this part of the layer occurs under the intrinsic stress, high temperature, and external force of the layer. In some embodiments, a disconnection region 11 is formed to separate the organic common layer 5 between two adjacent pixel regions 1, thereby effectively avoiding the mutual flow of holes and electrons in the adjacent pixel regions 1. In this way, when only some pixel regions 1 are controlled to light up, the lit pixel regions 1 will no longer transmit holes and electrons to their adjacent pixel regions 1, thereby avoiding the occurrence of undesirable light-emitting in these adjacent pixel regions 1.

In some embodiments, the light-emitting element layer 4 includes a cathode 34 located at a side of the organic common layer 5 facing away from the substrate 3. Since the first layer 9 and the second layer 10 can be used in the present disclosure to form a first opening 6 with a smaller volume, therefore, as multiple organic common layers 5 are recessed at the first opening 6, the first opening 6 can be filled to a greater extent. When the cathode 34 is subsequently formed, the cathode 34 can be continuous at the first opening 6 to avoid the disconnection of the cathode 34, improving the reliability of the cathode 34.

FIG. 26 is another flowchart of a method for manufacturing a display panel provided by some embodiments of the present disclosure. In an embodiment, as shown in FIG. 26, a process of step S1 can include following step S11 and step S12.

At step S11, a first layer 9 including a first groove 15 is formed on the substrate 3.

At step S12, a second layer 10 is formed at a side of the first layer 9 facing away from the second layer 10. The second layer 10 includes a second groove 16. In the direction perpendicular to the plane of the substrate 3, the second grooves 16 partially overlaps with the first groove 15, and a part of the second layer 10 is recessed at the first groove 15. The sidewall of the second layer 10 recessed at the first groove 15 is the second sidewall 8, and the sidewall of the first layer 9 opposite to the second sidewall 8 is the first sidewall 7.

In the above arrangement, the first layer 9 and the second layer 10 are two layers respectively arranged in different layers. By staggering the grooves in two films to form the first opening 6, in addition to using the first opening 6 to fracture the organic common layer 5, a step surface with fluctuation is formed between the portion of the first layer 9 exposed in the second groove 16 and the second layer 10 located above it. Compared with providing grooves in a single layer, the present disclosure can increase the length of the part of the organic common layer 5 extending in the non-pixel region 2 to a greater extent, so that the impedance of this part of the organic common layer 5 is increased to a greater extent, thereby suppressing the flow of holes and electrons in the pixel region 1 to the surrounding more effectively.

FIG. 27 is a process flowchart corresponding to FIG. 26 provided by some embodiments of the present disclosure. In some embodiments, as shown in FIG. 27, step S11 can include: forming a planarization layer 19 on the substrate 3, forming a first groove on the planarization layer 19, and reusing the planarization layer 19 as the first layer 9.

Step S12 can include forming a pixel definition layer 17 at a side of the planarization layer 19 facing away from the substrate 3, forming a second groove 16 and a second opening 18 on the pixel definition layer 17, and reusing the pixel definition layer 17 as the second layer 10. The second opening 18 is configured to define the pixel region 1.

In the panel structure, the planarization layer 19 is configured to realize the planarization of the layer, so it usually has a larger thickness. By reusing the planarization layer 19 as the first layer 9, the planarization layer 19 can be used to form the first opening 6 with a larger depth, the organic common layer 5 is easily fractured at the junction of the top surface of the planarization layer 19 and the first sidewall 7 in addition to the fracture at the bottom of the first opening 6. Therefore, the flow of holes and electrons between adjacent pixel regions 1 can be blocked to a greater extent. Since the organic common layer 5 is in direct contact with the pixel definition layer 17 in the non-pixel region 2, when the planarization layer 19 is reused as the first layer 9, and the pixel definition layer 17 is reused as the second layer 10, the organic common layer 5 can be directly recessed at the first opening 6 formed by the planarization layer 19 and the pixel definition layer 17, there is no other layers under the organic common layer 5, so the organic common layer 5 is more likely to have sharp corners at the bottom of the first opening 6, and the stress is more concentrated, thereby being more prone to fracture.

By reusing the planarization layer 19 as the first layer 9, and reusing the pixel definition layer 17 as the second layer 10, the first groove 15 and the second groove 16 can be respectively etched in the planarization layer 19 and the pixel definition layer 17 by only respectively changing the mask patterns corresponding to the pixel definition layer 17 and the planarization layer 19, which not only does not need to add a new process flow, but also lowers the process cost. In this way, it will not lead to an increase in the overall thickness of the panel, which is more conducive to achieve a thin and light display panel.

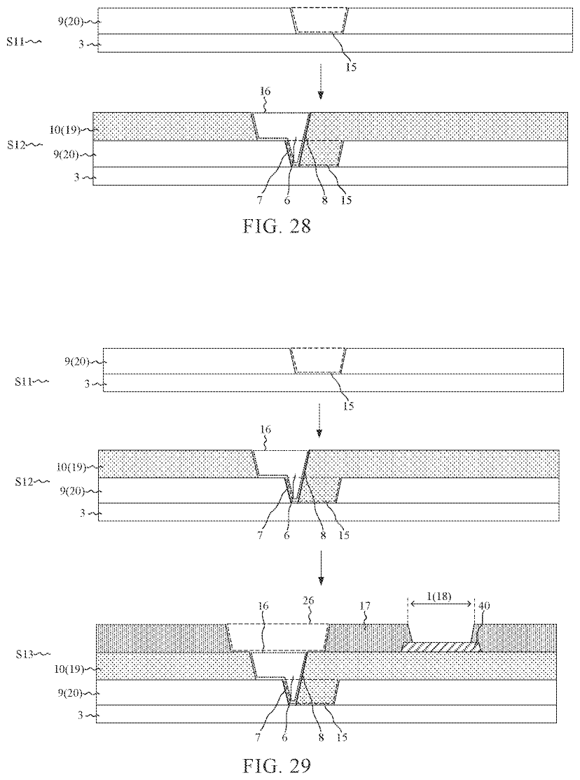

FIG. 28 is another process flowchart corresponding to FIG. 26 provided by some embodiments of the present disclosure. In some embodiments, as shown in FIG. 28, step S11 can include forming a first insulation layer 20 on the substrate 3, forming a first groove 15 on the first insulation layer 20, and reusing the first insulation layer 20 as the first layer 9.

Step S12 can include forming a planarization layer 19 at a side of the first insulation layer 20 facing away from the substrate 3, forming a second groove 16 on the planarization layer 19, and reusing the planarization layer 19 as a second layer 10.

Since the thickness of the planarization layer 19 is relatively large, when the planarization layer 19 is reused as the second layer 10, the extension length of the second sidewall 8 is relatively large, the organic common layer 5 is easily fractured at the junction of the top surface of the planarization layer 19 and the first sidewall 7 in addition to the fracture at the bottom of the first opening 6, thereby blocking the flow of holes and electrons between adjacent pixel regions 1 to a greater extent.

By reusing the first insulation layer 20 as the first layer 9, and reusing the planarization layer 19 as the second layer 10, the first groove 15 and the second groove 16 can be respectively etched on the first insulation layer 20 and the planarization layer 19 by only change the mask patterns corresponding to the first insulation layer 20 and the planarization layer 19, respectively, which not only does not need to add a new process flow, but also lowers the process cost. In this way, it will not lead to an increase in the overall thickness of the panel, which is more conducive to realizing a thin-light design of the display panel.

FIG. 29 is another process flowchart provided by some embodiments of the present disclosure. In some embodiments, with reference to FIG. 11, as shown in FIG. 29, after the planarization layer 19 is formed, the method includes step S13.

At step S13, a pixel definition layer 17 is formed at a side of the planarization layer 19 facing away from the substrate 3. A second opening 18 and a third opening 26 are formed on the pixel defining layer 17. The second opening 18 is configured to define a pixel region 1. The third opening 26 at least exposes the first opening 6 in a direction perpendicular to the plane of the substrate 3.

In this case, the pixel definition layer 17 is not be recessed at the first opening 6 formed by the planarization layer 19 and the first insulation layer 20. During forming the organic common layer 5, the pixel definition layer 17 can be prevented from filling the first opening 6, so that the organic common layer 5 is more likely to be fracture at the bottom of the first opening 6. The overall groove depth formed by the above three layers is larger, so the extension length of the organic common layer 5 between the non-pixel regions 2 is larger and the impedance is higher.

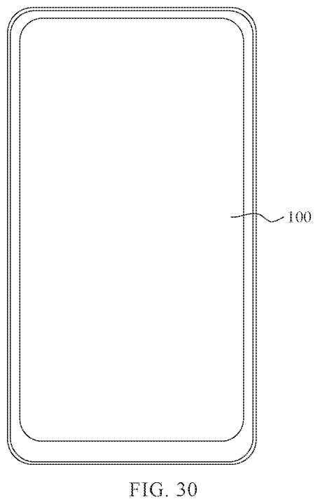

Based on the same or related concepts, the present disclosure also provides, in another aspect, a display apparatus. FIG. 30 is a schematic diagram of a display apparatus provided by some embodiments of the present disclosure. As shown in FIG. 30, the display apparatus includes the display panel 100 mentioned above. The specific structure of the display panel 100 has been described in detail in the above embodiments, and will not be repeated herein. It is appreciated that, the display apparatus shown in FIG. 30 is only a schematic illustration, and the display apparatus can be any electronic device with a display function, such as a mobile phone, a tablet computer, a laptop computer, an electronic paper book, or a television.

The above are merely some embodiments of the present disclosure, which, as mentioned above, are not configured to limit the present disclosure. Whatever within the principles of the present disclosure, including any modification, equivalent substitution, improvement, etc., shall fall into the protection scope of the present disclosure.

Finally, it should be noted that the technical solutions of the present disclosure are illustrated by the above embodiments, but not intended to limit thereto. Although the present disclosure has been described in detail in the foregoing embodiments, those skilled in the art can understand that the present disclosure is not limited to the specific embodiments described herein, and can make various obvious modifications, readjustments, and substitutions without departing from the scope of the present disclosure.

What is claimed is:

1. A display panel, wherein the display panel has pixel regions and at least one non-pixel region, and each of the at least one non-pixel region is at least located between two adjacent pixel regions of the pixel regions; and
wherein the display panel comprises:
a substrate;
a light-emitting element layer located at a side of the substrate and comprising an organic common layer; and
a first opening located in one of the at least one non-pixel region, wherein the first opening comprises a first sidewall and a second sidewall, wherein the first sidewall is a side surface of a first layer, and the second sidewall is a side surface of a second layer; and the first layer and the second layer are located at a side of the organic common layer facing towards the substrate, and the organic common layer forms a recessed structure at the first opening.

2. The display panel according to claim 1, wherein the organic common layer has a disconnection region that overlaps with the first opening in a direction perpendicular to a plane of the substrate.

3. The display panel according to claim 1, wherein the first sidewall and the second sidewall are two opposite sidewalls of the first opening.

4. The display panel according to claim 3, wherein, along a direction from the organic common layer to the substrate, the first sidewall is inclined towards the second sidewall, and the second sidewall is inclined towards the first sidewall.

5. The display panel according to claim 4, wherein the first sidewall intersects with the second sidewall.

6. The display panel according to claim 1, wherein the first layer comprises a first bottom surface close to the substrate, an angle A1 formed between the first sidewall and the first bottom surface satisfies 60°<A1<90°; and the second layer comprises a second bottom surface at a side close to the substrate, and an angle A2 formed between the second sidewall and the second bottom surface satisfies 60°<A2<90°;
wherein the light-emitting element layer further comprises a cathode located at a side of the organic common layer facing away from the substrate; and
wherein, in a first direction, a maximum distance L1 between the first sidewall and the second sidewall satisfies L1<2×d1, where d1 denotes a sum of a thickness of the cathode and a thickness of the organic common layer, and the first direction is a direction along which the two adjacent pixel regions are arranged.

7. The display panel according to claim 6, wherein, in the first direction, a minimum distance L2 between the first sidewall and the second sidewall satisfies L2>2×d2, where d2 denotes the thickness of the organic common layer.

8. The display panel according to claim 1, wherein the second layer is located at a side of the first layer facing away from the substrate;
wherein the first layer comprises a first groove, the second layer comprises a second groove, and in a direction perpendicular to a plane of the substrate, the second groove partially overlaps with the first groove, and a part of the second layer is recessed at the first groove; and
wherein a sidewall of the second layer recessed at the first groove is the second sidewall, and a sidewall of the first layer opposite to the second sidewall is the first sidewall.

9. The display panel according to claim 1, wherein the light-emitting element layer further comprises a pixel definition layer located at a side of the organic common layer facing towards the substrate, and the pixel definition layer comprises second openings for defining the pixel regions;
wherein the display panel further comprises a planarization layer located at a side of the pixel definition layer facing towards the substrate; and
wherein the first layer is the planarization layer, and the second layer is the pixel definition layer.

10. The display panel according to claim 1, wherein the light-emitting element layer further comprises a pixel definition layer located at a side of the organic common layer facing towards the substrate, and the pixel definition layer comprises second openings defining the pixel regions;
wherein the display panel further comprises a planarization layer and a first insulation layer, the planarization layer is located at a side of the pixel definition layer facing towards the substrate, and the first insulation layer is located at a side of the planarization layer facing towards the substrate; and
wherein the first layer is the first insulation layer, and the second layer is the planarization layer.

11. The display panel according to claim 10, wherein the pixel definition layer further comprises a third opening, and the third opening at least exposes the first opening in a direction perpendicular to a plane of the substrate.

12. The display panel according to claim 11, wherein the second layer is located at a side of the first layer facing away from the substrate;
wherein the first layer comprises a first groove, the second layer comprises a second groove, and in a direction perpendicular to a plane of the substrate, the second groove partially overlaps with the first groove, and a part of the second layer is recessed at the first groove;
wherein a sidewall of the second layer recessed at the first groove is the second sidewall, and a sidewall of the first layer opposite to the second sidewall is the first sidewall; and
wherein the second groove is located in the third opening in the direction perpendicular to the plane of the substrate.

13. The display panel according to claim 8, wherein the first groove penetrates the first layer, and the second groove penetrates the second layer.

14. The display panel according to claim 1, wherein the light-emitting element layer further comprises a pixel definition layer located at a side of the organic common layer facing towards the substrate, and the pixel definition layer comprising second openings for defining the pixel regions; and
the first layer and the second layer are located between the pixel definition layer and the organic common layer, and are arranged in a same layer.

15. The display panel according to claim 1, wherein the pixel regions comprise a blue pixel region configured to emit blue light, and the blue pixel region is located at a side of the second sidewall of the first opening; and
the second layer is located at a side of the first layer facing away from the substrate.

16. The display panel according to claim 1, wherein the first sidewall comprises a first bottom edge close to the substrate, and a first top edge away from the substrate; and the second sidewall comprises a second bottom edge close to the substrate, and a second top edge away from the substrate; and a distance between the second top edge and the second bottom edge of the second sidewall is greater than a distance between the first top edge and the first bottom edge of the first sidewall; and
wherein the pixel regions comprise a blue pixel region configured to emit blue light, and the blue pixel region is located at a side of the second sidewall of the first opening.

17. The display panel according to claim 1, wherein the light-emitting element layer further comprises a cathode located at a side of the organic common layer facing away from the substrate; and
wherein the display panel further comprises a filling layer located at the first opening and located between the organic common layer and the cathode.

18. The display panel according to claim 1, wherein the light-emitting element layer further comprises a cathode located at a side of the organic common layer facing away from the substrate, wherein the cathode is communicated in the pixel regions and the at least one non-pixel region.

19. The display panel according to claim 1, wherein the first opening comprises a strip-shaped opening, and an extending direction of the strip-shaped opening intersects with a direction along which the two adjacent pixel regions are arranged.

20. The display panel according to claim 1, wherein the first opening comprises an annular opening surrounding one of the pixel regions.

21. The display panel according to claim 1, wherein the first opening is grid-shaped having a plurality of holes, and the pixel regions are exposed in the plurality of holes of the first opening in a direction perpendicular to a plane of the substrate.

22. The display panel according to claim 1, further comprising:
a step structure, wherein the step structure is located in one of the at least one non-pixel region and located at a side of the organic common layer facing towards the substrate.

23. The display panel according to claim 22, wherein the light-emitting element layer further comprises a cathode located at a side of the organic common layer facing away from the substrate; and
wherein the step structure comprises a third groove, and in a direction perpendicular to a plane of the substrate, the third groove has a depth greater than a thickness of the organic common layer and smaller than or equal to a sum of the thickness of the organic common layer and a thickness of the cathode.

24. The display panel according to claim 1, wherein the light-emitting element layer further comprises:
an anode located at a side of the substrate;
a light-emitting layer located at a side of the anode facing away from the substrate; and
a cathode located at a side of the light-emitting layer facing away from the substrate,
wherein the organic common layer comprises a hole transmission layer and a hole injection layer that are located between the anode and the light-emitting layer; and/or,
wherein the organic common layer comprises an electron transmission layer and an electron injection layer that are located between the light-emitting layer and the cathode; and/or,
wherein the light-emitting layer comprises a first light-emitting layer and a second light-emitting layer that overlap with each other in a direction perpendicular to a plane of the substrate, and the organic common layer comprises a charge generation layer located between the first light-emitting layer and the second light-emitting layer.

25. A method for manufacturing a display panel, wherein the display panel has pixel regions and at least one non-pixel region, and each of the at least one non-pixel region is at least located between two adjacent pixel regions of the pixel regions;
wherein the display panel comprises:
a substrate;
a light-emitting element layer located at a side of the substrate and comprising an organic common layer; and
a first opening located in one of the at least one non-pixel region, wherein the first opening comprises a first sidewall and a second sidewall, wherein the first sidewall is a side surface of a first layer, and the second sidewall is a side surface of a second layer; and the first layer and the second layer are located at a side of the organic common layer facing towards the substrate, and the organic common layer forms a recessed structure at the first opening;
wherein the method comprises:
forming the first layer and the second layer on the substrate, wherein the first sidewall of the first layer and the second sidewall of the second layer form the first opening located in the one of the at least one non-pixel region; and
forming the light-emitting element layer at a side of the first layer and the second layer that faces away from the substrate, wherein the light-emitting element layer comprises the organic common layer.

26. The method according to claim 25, wherein said forming the first layer and the second layer on the substrate comprises:
forming the first layer on the substrate, the first layer comprising a first groove;
forming the second layer at a side of the first layer facing away from the substrate, wherein the second layer comprises a second groove, and in a direction perpendicular to a plane of the substrate, the second groove partially overlaps with the first groove, and a part of the second layer is recessed at the first groove; and
wherein a sidewall of the second layer recessed at the first groove is the second sidewall, and a sidewall of the first layer opposite to the second sidewall is the first sidewall.

27. A display apparatus, comprising a display panel, wherein the display panel has pixel regions and at least one non-pixel region, and each of the at least one non-pixel region is at least located between two adjacent pixel regions of the pixel regions; and
wherein the display panel comprises:
a substrate;
a light-emitting element layer located at a side of the substrate and comprising an organic common layer; and
a first opening located in one of the at least one non-pixel region, wherein the first opening comprises a first sidewall and a second sidewall, wherein the first sidewall is a side surface of a first layer, and the second sidewall is a side surface of a second layer; and the first layer and the second layer are located at a side of the organic common layer facing towards the substrate, and the organic common layer forms a recessed structure at the first opening.
